(19) United States
(12) Patent Application Publication
(10) Pub. No.: US 2011/0303152 A1
(43) Pub. Date: Dec. 15, 2011

(54) SUPPORT STRUCTURE, PROCESSING CONTAINER STRUCTURE AND PROCESSING APPARATUS

(75) Inventors: Shinji ASARI, Oshu-Shi (JP); Izumi Sato, Oshu-Shi (JP); Yuichiro Morozumi, Nirasaki-Shi (JP)

(73) Assignee: Tokyo Electron Limited, Minato-Ku (JP)

(21) Appl. No.: 13/159,954

(22) Filed: Jun. 14, 2011

(30) Foreign Application Priority Data
Jun. 15, 2010 (JP) 2010-136482

(51) Int. Cl. C23C 16/46; C23C 16/458

(52) U.S. Cl. 118/725; 118/728; 118/715

(57) ABSTRACT

A support structure for supporting a plurality of objects to be processed and to be disposed in a processing container structure in which a processing gas flows horizontally from one side to the opposite side, includes a top plate section; a bottom section; and a plurality of support posts connecting the top plate section and the bottom section, wherein a plurality of support portions for supporting the objects to be processed are formed in each support post at a predetermined pitch along the longitudinal direction, and the distance between the topmost support portion of the support portions of each support post and the top plate section as well as the distance between the lowermost support portion of the support portions of each support post and the bottom section are set not more than the pitch of the support portions. The support structure can prevent the occurrence of a turbulent gas flow in the top and bottom areas of the processing container structure.

### CROSS-REFERENCE TO RELATED APPLICATION

This application claims the benefit of Japanese Patent Application No. 2010-136482, filed on Jun. 15, 2010, the disclosure of which is incorporated herein by reference in its entirety.

### BACKGROUND OF THE INVENTION

1. Field of the Invention

The present invention relates to a support structure for supporting objects to be processed, such as semiconductor wafers, and to a processing container structure and a processing apparatus.

2. Description of the Background Art

In the manufacturing of a semiconductor integrated circuit, a semiconductor wafer, e.g. comprised of a silicon substrate, is generally subjected to various types of processing, such as film-forming processing, etching, oxidation, diffusion processing, modification, removal of a natural oxide film, etc. Such processing is carried out by using a single-wafer processing apparatus which processes wafers in a one-by-one manner, or a batch processing apparatus which processes a plurality of wafers at a time. When processing of a semiconductor wafer is carried out e.g. by using a vertical batch processing apparatus as disclosed e.g. in patent document 1, semiconductor wafers are first transferred from a cassette, which can house a plurality of, e.g. about 25, wafers, to a vertical wafer boat where the wafers are supported in multiple stages.

The wafer boat can generally hold about 30 to 150 wafers, depending on the wafer size. After the wafer boat, housing wafers therein, is loaded into an evacuable processing container from below, the interior of the processing container is kept airtight. A predetermined heat treatment of the wafers is then carried out while controlling processing conditions, such as the flow rate of a processing gas, the processing pressure, the processing temperature, etc. Taking film-forming processing as an example of heat treatment, known film-forming methods include CVD (chemical vapor deposition) (patent document 2) and ALD (atomic layer deposition).

For the purpose of improving the characteristics of circuit elements, a demand exists for reducing heat history in the process of manufacturing a semiconductor integrated circuit. An ALD method, which involves intermittently supplying a raw material gas, etc. so as to repeatedly form one layer to a few layers of a film at the atomic or molecular level and which is capable of performing intended processing without exposing wafers to excessively high temperatures, is therefore becoming more frequently used (patent documents 3 and 4).

### PATENT DOCUMENTS

Patent document 1: Japanese Patent Laid-Open Publication No. H6-275608
Patent document 2: Japanese Patent Laid-Open Publication No. 2004-006551
Patent document 3: Japanese Patent Laid-Open Publication No. H6-45256
Patent document 4: Japanese Patent Laid-Open Publication No. H11-87341

### SUMMARY OF THE INVENTION

It is an object of the present invention to provide a support structure, a processing container structure and a processing apparatus, which can prevent the occurrence of a turbulent gas flow in the top and bottom areas of the support structure which supports objects to be processed, thereby enhancing the in-plane uniformity of the thickness of a film formed and the quality of the film.

In order to achieve the object, the present invention provides a support structure for supporting a plurality of objects to be processed and to be disposed in a processing container structure in which a processing gas flows horizontally from one side to the opposite side, comprising: a top plate section; a bottom section; and a plurality of support posts connecting the top plate section and the bottom section, wherein a plurality of support portions for supporting the objects to be processed are formed in each support post at a predetermined pitch along the longitudinal direction, and a distance between the topmost support portion of the support portions of each support post and the top plate section as well as a distance between the lowermost support portion of the support portions of each support post and the bottom section are set not more than the pitch of the support portions.

The support structure can prevent the occurrence of a turbulent gas flow in the top and bottom areas of the processing container structure, thereby preventing a decrease in the in-plane uniformity of the thickness of a film formed and a decrease in the quality of the film.

The present invention also provides a processing container structure for housing a plurality of objects to be processed and in which a processing gas flows horizontally from one side to the opposite side, comprising: a quartz processing container with a closed top and an open bottom, configured to house the objects to be processed which are supported in a support structure; a nozzle housing area for housing a gas nozzle, provided on one side of the processing container along the longitudinal direction; and a slit-like exhaust port provided in the side wall of the processing container along the longitudinal direction at a position opposite the nozzle housing area, the upper end of the exhaust port being at the same or a higher level than the upper end of the support structure, and the lower end of the exhaust port being at the same or a lower level than the lower end of the support structure.

According to the processing container structure, a gas that has flown horizontally through the spaces between the processing objects supported in the support structure is discharged, without change in the flow direction, from the slit-like exhaust port. This can prevent the occurrence of a turbulent gas flow in the top and bottom areas of the processing container structure, thereby preventing a decrease in the in-plane uniformity of the thickness of a film formed and a decrease in the quality of the film.

The present invention also provides a processing apparatus for carrying out predetermined processing of a plurality of objects to be processed, comprising: a container structure having an open-bottom for housing the objects to be processed and in which a processing gas flows horizontally from one side to the opposite side; a lid for closing the bottom opening of the processing container structure; a support structure for supporting the objects to be processed and which can be inserted into and withdrawn from the processing container structure; a gas introduction means including a gas nozzle for introducing a gas into the processing container structure; an exhaust means for exhausting the atmosphere in the processing container structure; and a heating means for heating the processing objects, wherein the processing container structure comprises a quartz processing container with a closed top and an open bottom, configured to house the objects to be processed which are supported in a support structure; a nozzle housing area for housing the gas nozzle, provided on one side of the processing container along the longitudinal direction; and a slit-like exhaust port provided in the side wall of the processing container along the longitudinal direction at a position opposite the nozzle housing area, the upper end of the exhaust port being at the same or a higher level than the upper end of the support structure, and the lower end of the exhaust port being at the same or a lower level than the lower end of the support structure, and wherein the support structure comprises a top plate section; a bottom section; and a plurality of support posts connecting the top plate section and the bottom section, wherein a plurality of support portions for supporting the objects to be processed are formed in each support post at a predetermined pitch along the longitudinal direction, and a distance between the topmost support portion of the support portions of each support post and the top plate section as well as a distance between the lowermost support portion of the support portions of each support post and the bottom section are set not more than the pitch of the support portions.

The support structure, the processing container structure and the processing apparatus of the present invention can achieve the following advantageous effects.

According to the present invention, the occurrence of a turbulent gas flow can be prevented in the top and bottom areas of the support structure. This can prevent a decrease in the in-plane uniformity of the thickness of a film formed and a decrease in the quality of the film.

According to the present invention, a gas that has flown horizontally through the spaces between processing objects supported in the support structure is discharged, without change in the flow direction, from the slit-like exhaust port. This can prevent the occurrence of a turbulent gas flow in the top and bottom areas of the processing container structure, thereby preventing a decrease in the in-plane uniformity of the thickness of a film formed and a decrease in the quality of the film.

According to the present invention, the occurrence of a turbulent gas flow can be prevented in the top and bottom areas of the processing container structure. This can prevent a decrease in the in-plane uniformity of the thickness of a film formed and a decrease in the quality of the film.

### BRIEF DESCRIPTION OF THE DRAWINGS

FIG. 1 is a vertical sectional view of an exemplary processing apparatus including a support structure according to the present invention;

FIG. 2 is a cross-sectional view of a processing container structure portion of the processing apparatus;

FIG. 3 is a perspective view of the processing container;

FIG. 4 is a plan view of a first embodiment of a support structure according to the present invention;

FIG. 5 is a perspective view of a lid member provided in the support structure;

FIG. 6 is a perspective view of a space cover member provided in a heat-retaining stand;

FIGS. 7(A) through 7(C) are graphs showing the results of experiments carried out by using the present invention;

FIGS. 8(A) and 8(B) are graphs showing the results of evaluation of the present invention;

FIG. 9 is a plan view of a second embodiment of a support structure according to the present invention;

FIG. 10 is a plan view of a third embodiment of a support structure according to the present invention;

FIG. 11 is a schematic view of a processing container according to a fourth embodiment of the present invention;

FIG. 12 is a schematic view of a comparative batch processing apparatus; and

FIG. 13 is a front view of an exemplary wafer boat.

### DETAILED DESCRIPTION OF THE PREFERRED EMBODIMENTS

Preferred embodiments of a support structure, a processing container structure and a processing apparatus according to the present invention will now be described in detail with reference to the drawings.

### First Embodiment

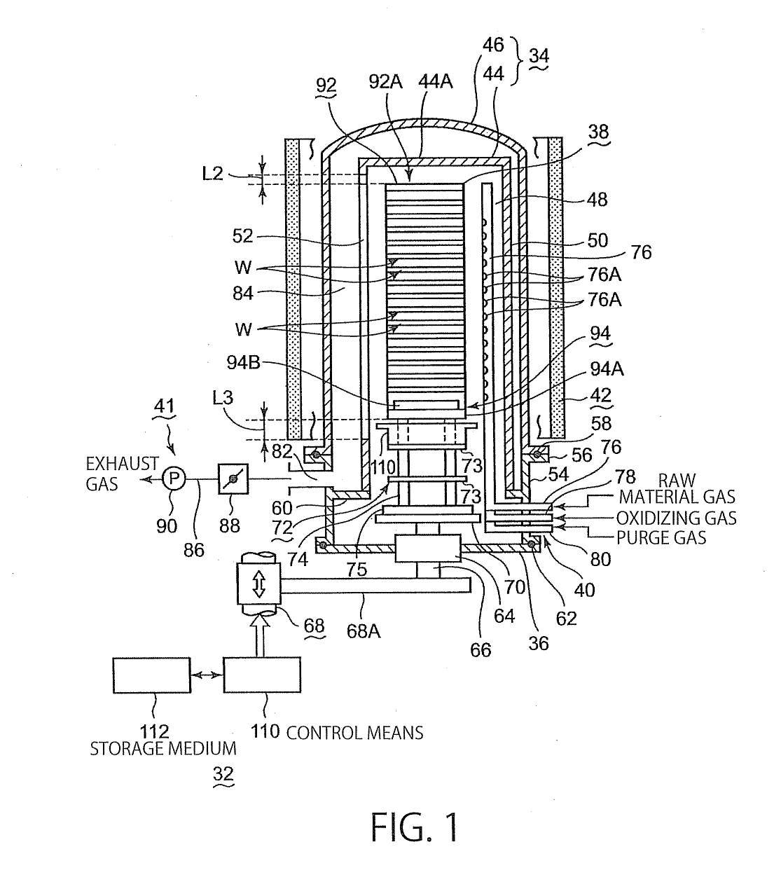

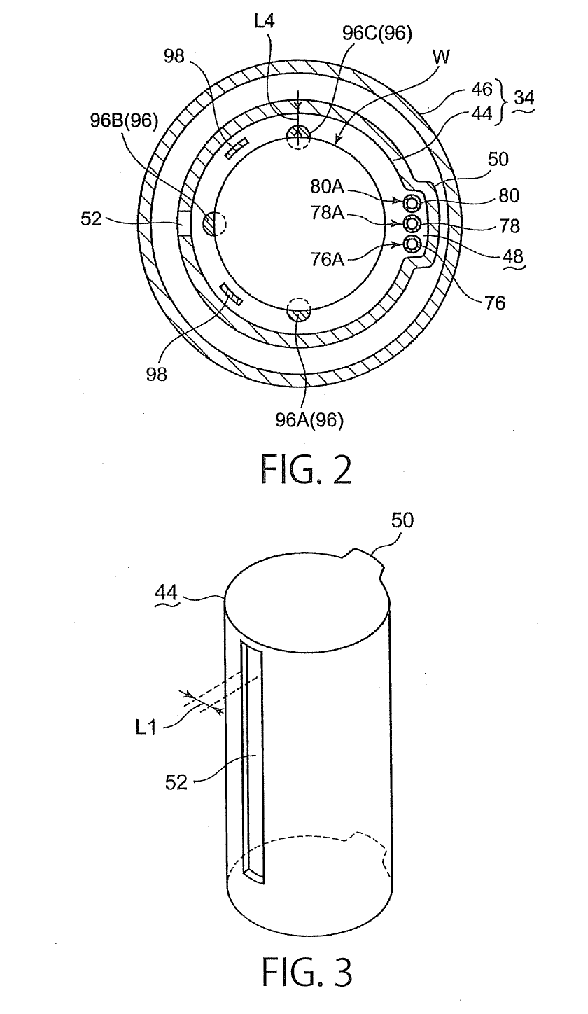

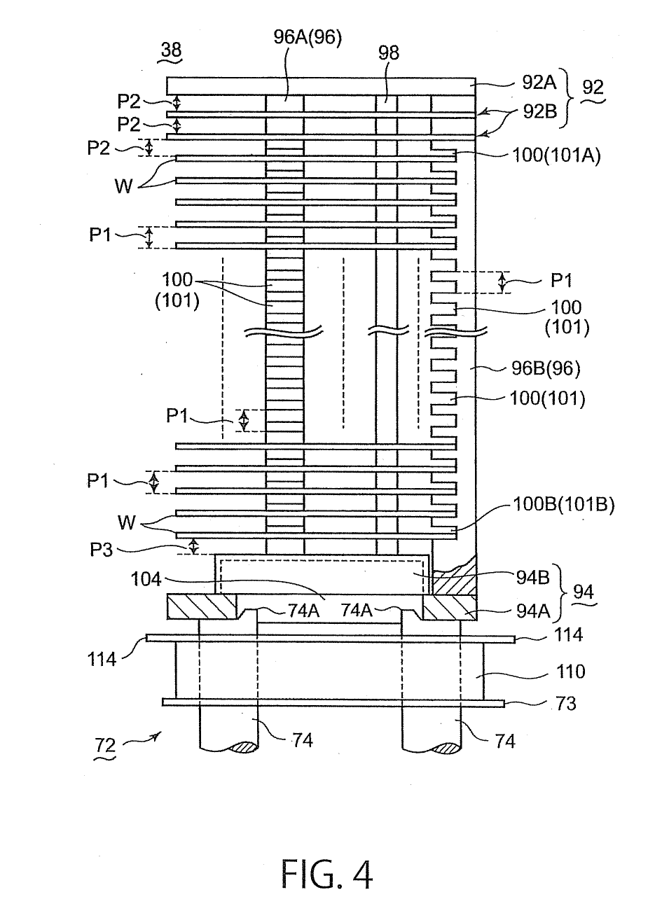

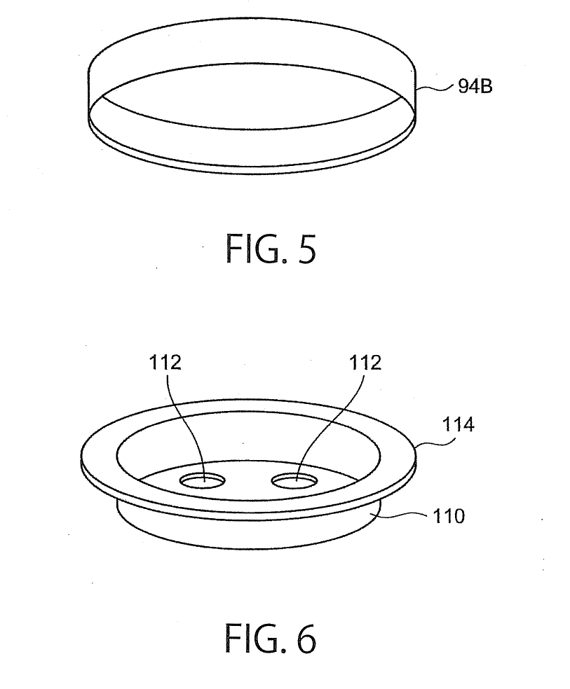

FIG. 1 is a vertical sectional view of an exemplary processing apparatus including a support structure according to the present invention; FIG. 2 is a cross-sectional view of a processing container structure portion of the processing apparatus; FIG. 3 is a perspective view of the processing container; FIG. 4 is a plan view of a first embodiment of a support structure according to the present invention; FIG. 5 is a perspective view of a lid member provided in the support structure; and FIG. 6 is a perspective view of a space cover member provided in a heat-retaining stand.

The following description illustrates an exemplary case in which the processing apparatus performs film-forming processing to form a film on a semiconductor wafer as an object to be processed. As shown in FIG. 1, the processing apparatus 32 mainly comprises a processing container structure 34 for housing objects to be processed, a lid 36 for hermetically closing the opening at the lower end of the processing container structure 34, a support structure 38 for supporting a plurality of semiconductor wafers W as objects to be processed at a predetermined pitch and which is to be inserted into and withdrawn from the processing container structure 34, a gas introduction means 40 for introducing a necessary gas into the processing container structure 34, an exhaust means 41 for exhausting the atmosphere in the processing container structure 34, and a heating means 42 for heating the semiconductor wafers W.

The processing container structure 34 is mainly comprised of a cylindrical processing container 44 with a closed top and an open bottom, and a cylindrical cover container 46 with a closed top and an open bottom, covering the exterior of the processing container 44. The processing container 44 and the cover container 46 are both composed of quartz which is resistant to heat, and are coaxially arranged in a double tube structure.

The ceiling portion of the processing container 44 is formed flatly. A nozzle housing area 48 for housing the below-described gas nozzles is formed on one side of the processing container 44 along the longitudinal direction. As shown in FIG. 2, the nozzle housing area 48 is formed inside an outwardly-bulging portion 50 of the side wall of the processing container 44.

A slit-like exhaust port 52 (see FIG. 3), whose width L1 is constant along the longitudinal direction (vertical direction), is formed in the side wall of the processing container 44 at a position opposite the nozzle housing area 48 so that the atmosphere in the processing container 44 can be exhausted. The length of the slit-like exhaust port 52 is equal to or longer than the length of the support structure 38; the upper end of the exhaust port 52 is at the same or a higher level than the upper end of the support structure 38, and the lower end of the exhaust port 52 is at the same or a lower level than the lower end of the support structure 38.

More specifically, the distance L2 between the upper end of the support structure 38 and the upper end of the exhaust port 52 in the height direction is generally within the range of about 0 to 5 mm, and the distance L3 between the lower end of the support structure 38 and the lower end of the exhaust port 52 in the height direction is generally within the range of about 0 to 350 mm. The width L1 is generally within the range of about 1 to 6 mm, preferably within the range of about 2.5 to 5.0 mm. The lower end of the processing container structure 34 is supported by a cylindrical manifold 54 e.g. made of stainless steel.

The manifold 54 has, at its upper end, a flange portion 56 on which the lower end of the cover container 46 is mounted and supported. A sealing member 58, such as an O-ring, is interposed between the flange portion 56 and the lower end of the cover container 46 to keep the interior of the cover container 46 in a hermetic condition. Further, a ring-shaped support portion 60 is provided on an upper portion of the interior wall of the manifold 54, and the lower end of the processing container 44 is mounted and supported on the support portion 60. The lid 36 is hermetically mounted to the bottom opening of the manifold 54 via a sealing member 62, such as an O-ring, to hermetically close the bottom opening side of the processing container structure 34, i.e. the opening of the manifold 54. The lid 36 is, for example, formed of stainless steel.

A rotating shaft 66, penetrating though the lid 36, is provided via a magnetic fluid sealing portion 64 in the center of the lid 36. The lower end of the rotating shaft 66 is rotatably supported on the arm 68A of a lifting means 68 comprised of a boat elevator. The rotating shaft 66 is rotated by means of a not-shown motor. A rotating plate 70 is provided on the upper end of the rotating shaft 66. The support structure 38 for holding wafers W is placed on the rotating plate 70 via a quartz heat-retaining stand 72. Thus, the lid 36 moves vertically together with the support structure 38 by vertically moving the lifting means 68, so that the support structure 38 can be inserted into and withdrawn from the processing container structure 34.

The quartz heat-retaining stand 72 includes four support posts 74 (only two posts are shown in FIGS. 1 and 4) mounted in an upright position on a base 75 and on which the support structure 38 is mounted and supported. The support posts 74 are provided with a plurality of heat-retaining plates 73 arranged at appropriate intervals in the longitudinal direction of the support posts 74.

On the other hand, the gas introduction means 40 for introducing a gas into the processing container 44 is provided in the manifold 54. More specifically, the gas introduction means 40 includes a plurality of, for example three as depicted, quartz gas nozzles 76, 78, 80. The gas nozzles 76 to 80 are disposed in the processing container 44 along the longitudinal direction, and the base end portions of the gas nozzles, bent in a letter “L” shape, penetrate through the manifold 54 and are thus supported.

As shown in FIG. 2, the gas nozzles 76 to 80 are disposed in the nozzle housing area 48 of the processing container 44 in a line along the circumferential direction. Gas holes 76A, gas holes 78A and gas holes 80A are formed in the gas nozzles 76, 78 and 80, respectively, at a predetermined pitch along the longitudinal direction of the nozzles so that a gas can be ejected in a horizontal direction from each of the gas holes 76A to 80A. The predetermined pitch of the gas holes 76A to 80A is set equal to the pitch of the wafers W supported in the support structure 38, and the height position of each of the gas holes 76A to 80A is set to lie midway between vertically adjacent wafers W so that the respective gases can be supplied effectively to the spaces between the wafers W.

Examples of usable gases may include a raw material gas, an oxidizing gas and a purge gas. Such gases can be supplied as necessary though the gas nozzles 76 to 80 while controlling the flow rate of each gas. In this embodiment zirconium tetramethyl is used as a raw material gas, ozone is used as an oxidizing gas, and N₂ gas is used as a purge gas to form a ZrOx film by ALD. The type of a gas to be used should, of course, be changed according to the type of a film to be formed.

A gas outlet 82 is formed in an upper portion of the side wall of the manifold 54 and above the support portion 60 so that the atmosphere in the processing container 44, exhausted from the exhaust port 52 into the space 84 between the processing container 44 and the cover container 46, can be exhausted out of the system. The gas outlet 82 is provided with the exhaust means 41. The exhaust means 41 includes an exhaust passage 86 which is connected to the gas outlet 82 and in which a pressure regulating valve 88 and a vacuum pump 90 are interposed for vacuuming. The width L1 of the exhaust port 52 is set in the range of 1 to 6 mm so that the atmosphere in the processing container 44 can be effectively exhausted. The heating means 42 for heating the wafers W has a cylindrical shape, covering the exterior of the cover container 46.

<Support Structure>

The support structure 38, comprised of a wafer boat, will now be described. As described above, the entire support structure 38 is formed of quartz which is heat resistant. As shown in FIG. 4, the support structure 38 includes a top plate section 92 located at the upper end of the structure, a bottom section 94 located at the lower end of the structure, and a plurality of support posts 96 which connect the top plate section 92 and the bottom section 94 and which support wafers W in multiple stages. In this embodiment, the support posts 96 consist of three support posts 96A, 96B, 96C (see FIG. 2) which are arranged at equal intervals along the semicircular arc portion of the circular contour of the wafer W.

Transfer of wafers is performed from the other semicircular arc side where the support posts 96A to 96C are not provided. Plate-like quartz reinforcing support posts 98 (see FIG. 2), connecting the top plate section 92 and the bottom section 94, are provided approximately midway between the support posts 96A and 96B and between the support posts 96B and 96C to increase the strength of the wafer boat.

Support portions 100 for supporting wafers W are formed on the inner side of each of the three support posts 96A to 96C at a predetermined pitch P1 along the longitudinal direction. The support portions 100 are comprised of support grooves 101 formed by cutting the inner sides of the support posts 96A to 96C. Wafers W can be supported in multiple stages by placing peripheral portions of the wafers W on the support grooves 101. The diameter of the wafers W is, for example, 300 mm, and about 50 to 150 wafers W can be supported in the wafer boat. The pitch P1 may be generally in the range of about 6 to 16 mm, and in this embodiment is set at about 6.5 mm.

The top plate section 92 consists of a topmost main top plate 92A, and one or more secondary top plates 92B disposed under the main top plate 92A. Two secondary top plates 92B are depicted in FIG. 4. The main top plate 92A and the secondary top plates 92B are spaced apart from each other by a pitch P2, and are provided fixedly e.g. by welding. Further, the topmost support portion 100A (support groove 101A) of the support portions 100 of each support post and the top plate section 92, in particular the lowermost secondary top plate 92B, are also spaced apart by the pitch P2.

The distance between the topmost support portion 100A of each support post and the top plate section 92 is set not more than the pitch of the support portions 100, i.e. the following relation holds: pitch P2≦pitch P1. This can prevent the occurrence of a turbulent gas flow in the top area of the support structure 38, the wafer boat.

The pitch P2 is preferably set equal to the pitch P1, i.e. P1=P2, in order to more effectively prevent the occurrence of a turbulent gas flow. The lower limit of the pitch P2 should preferably be ½ of the pitch P1. If the pitch P2 is smaller than the lower limit, the exhaust conductance will be low in the top plate section 92. Therefore, a gas is likely to flow into the space between the wafers W and the processing container 44, which may result in decreased in-plane uniformity of the thickness of a film formed on the wafers W. The pitch P2 may not necessarily be constant, and may take various different values in the above-described range in the same wafer boat.

The bottom section 94 of the support structure 38 is mainly comprised of a ring-shaped quartz main bottom plate 94A having a central hole 104, and a quartz lid member 94B that closes the hole 104. The main bottom plate 94A is ring-shaped with the hole 104 formed in the center. A raised portion 74A at the top of each support post 74 of the heat-retaining stand 72 is engaged with the peripheral surface of the hole 104 to hold the entire support structure 38. The lid member 94B has a shape as shown in FIG. 5. The provision of the lid member 94B prevents a gas from leaking downward through the hole 104 of the main bottom plate 94A.

The lowermost support portion 100B of the support portions 100 of each support post and the lid member 94B are spaced apart by a distance corresponding to a pitch P3. The distance between the lowermost support portion 100B of each support post and the bottom section 94 is set not more than the pitch of the support portions 100, i.e. the following relation holds: pitch P3≦pitch P1. This can prevent the occurrence of a turbulent gas flow in the bottom area of the support structure 38, the wafer boat. The lower limit of the pitch P3 should preferably be ½ of the pitch P1. If the pitch P3 is smaller than the lower limit, the exhaust conductance will be low in the area. Therefore, a gas is likely to flow into the space between the wafers W and the processing container 44, which may result in decreased in-plane uniformity of the thickness of a film formed on the wafers W. The pitch P2 may not necessarily be constant, and may take various different values in the above-described range in the same wafer boat.

A quartz cover member 110 as shown in FIG. 6, which closes the space under the main bottom plate 94A, is provided on the topmost heat-retaining plate 73 of the heat-retaining stand 72. The cover member 110 has four support post holes 112 (only two holes are shown in FIG. 6) for insertion of the support posts 74. The cover member 110 also has, at its upper end, a horizontally extending ring-shaped flange portion 114. The gap between the peripheral end of the flange portion 114 and the inner periphery of the processing container 44 is made as narrow as possible to minimize the amount of a gas that flows into the space below the bottom section 94 of the support structure 38, thereby preventing the occurrence of a turbulent gas flow.

In this embodiment the distance L4 (see FIG. 2) between the outer periphery of the support structure 38 and the inner periphery of the processing container 44 (excluding the nozzle housing area 48) is set very small so as to reduce the amount of a gas that flows through the space between the support structure 38 and the processing container 44. The distance L4 is generally within the range of 5 to 20 mm, and is set e.g. at about 18 mm in this embodiment.

Returning to FIG. 1, the overall operation of the thus-constructed processing apparatus 32 is controlled by a control means 110 e.g. comprised of a computer. A computer program for performing the operation is stored in a storage medium 112 such as a flexible disk, a CD (compact disk), a hard disk, a flash memory or a DVD.

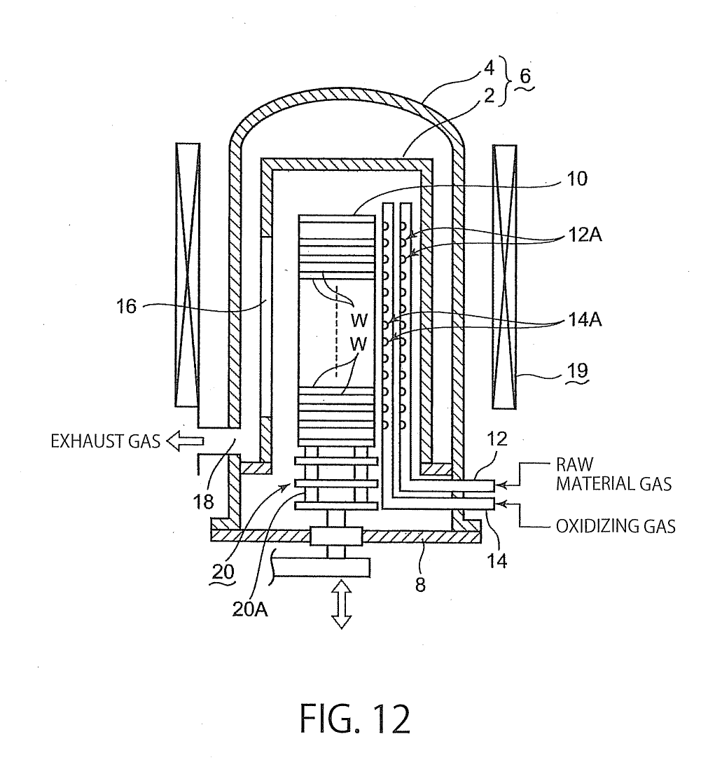

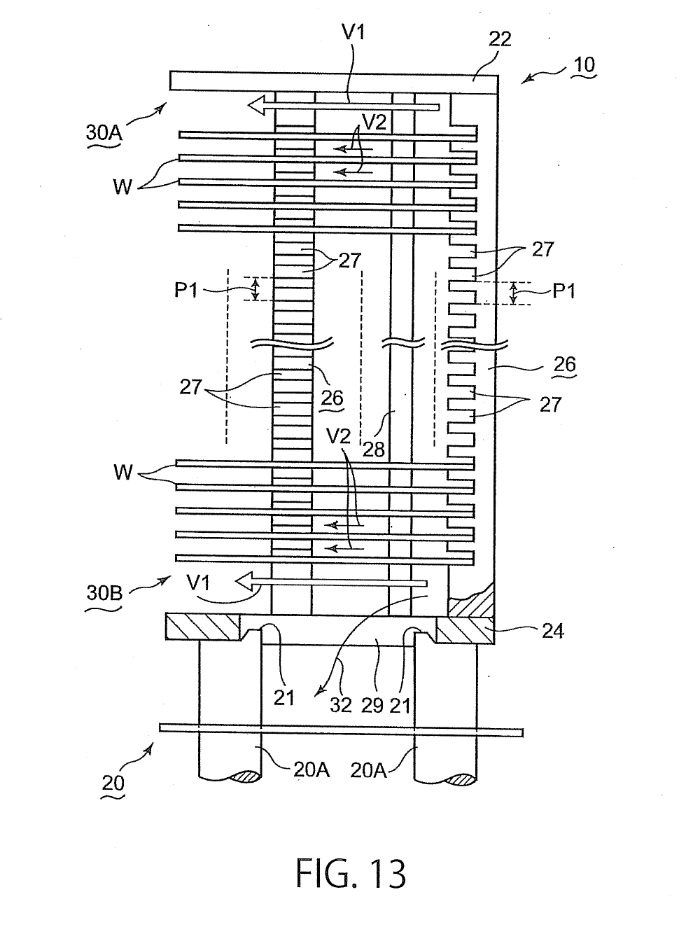

Though the above-described processing apparatus has the following features: the exhaust port 52 of the processing container 44 has a long length equal to or longer than the length of the support structure (wafer boat) 38; and no large space is provided in the top and bottom areas of the support structure 38, it is possible to apply only one of the two features in the conventional processing apparatus shown in FIGS. 12 and 13.

<Operation>

A film-forming processing, carried out by using the thus-constructed processing apparatus 32, will now be described. The following description illustrates the formation of a film, e.g. a ZrOx film, by the ALD method comprising a repetition of the cycle of supplying a raw material gas, e.g. zirconium tetramethyl, and an oxidizing gas, e.g. ozone, each in a pulsed manner for a predetermined time period. N₂ gas, for example, is used as a purge gas.

First, the support structure 38 comprised of the wafer boat, holding a large number of, for example 50 to 150, 300-mm wafers W at room temperature, is raised and loaded into the processing container 44 of the processing container structure 34, which has been brought to a predetermined temperature, and then the processing container 44 is hermetically closed by closing the bottom opening of the manifold 54 with the lid 36.

While keeping the interior of the processing container 44 at a predetermined processing pressure by continuously vacuuming the processing container 44, the temperature of the wafers W is raised to a processing temperature by increasing the power supplied to the heating means 42, and the processing temperature is maintained. The raw material gas is supplied from the gas nozzle 76 of the gas introduction means 40, ozone gas is supplied from the gas nozzle 78, and the purge gas is supplied from the gas nozzle 80. More specifically, the raw material gas is ejected horizontally from the gas holes 76A of the gas nozzle 76, ozone gas is ejected horizontally from the gas holes 78A of the gas nozzle 78, and the purge gas is ejected horizontally from the gas holes 80A of the gas nozzle 80. The raw material gas reacts with the ozone gas to form a ZrOx film on the surfaces of the wafers W supported in the rotating support structure 38.

The raw material gas and the oxidizing gas are supplied alternately and repeatedly in a pulsed manner as described above, and a purge period is provided between every consecutive time periods during which the processing gases are supplied. The purge gas is supplied during the purge period to promote discharge of the remaining processing gases. The respective gases, ejected from the gas holes 76A to 80A of the gas nozzles 76 to 80, flow horizontally toward the oppositely-located slit-like exhaust port 52 while passing between the wafers W supported in multiple stages, flow through the exhaust port 52 into the space 84 between the processing container 44 and the cover container 46, and are discharged through the gas outlet 82 to the outside of the processing container structure 34.

The cross-sectional area of the slit-like exhaust port 52 is set within the rage of one to two times the cross-sectional area of the exhaust passage 86 provided with the vacuum pump 90, so that the gases can be smoothly exhausted without allowing the gases to remain in the processing container 44. Because the gas holes 76A to 80A are arranged such that each gas hole lies at the same level as the space between adjacent wafers W, the respective gases flow in substantially laminar flow without causing a turbulent flow in the space between adjacent wafers W.

As is described hereafter, the conventional wafer boat as shown in FIGS. 12 and 13 has large spaces 30A, 30B (see FIG. 13), having a vertical width larger than the pitch P1 of wafers, in the top and bottom areas of the wafer boat. A fast gas flow will be produced in the spaces 30A, 30B, which may cause a turbulent gas flow. The wafer boat of the present invention eliminates such large spaces 30A, 30B and can therefore prevent the occurrence of a turbulent gas flow.

In particular, the top plate section 92, consisting of the main top plate 92A and the secondary top plates 92B, is provided in the top area of the support structure 38, and the distance between the main top plate 92A and the vertically adjacent secondary top plate 92B as well as the pitch P2 of the secondary top plates 92B are set not more than the pitch P1 of wafers W. Accordingly, the flow velocity of a gas, flowing between the main top plate 92A and the adjacent secondary top plate 92B and between the secondary top plates 92B, can be made approximately equal to the flow velocity of the gas flowing between the wafers W. This can prevent the occurrence of a turbulent gas flow in the top area of the support structure 38.

The pitch P2 is preferably equal to the pitch P1: P1=P2. However, because a dummy wafer is generally placed on the topmost support grooves 101A of the support portions 100A, the pitch P2 may be smaller than the pitch P1. Since the occurrence of a turbulent gas flow can thus be prevented in the top area of the support structure 38, the in-plane uniformity of the thickness of a film, formed on the surfaces of wafers W lying in the top area, and the quality of the film can be enhanced.

In the bottom area of the support structure 38, the central hole 104 of the ring-shaped main bottom plate 94A, constituting part of the bottom section 94, is closed with the lid member 94B. Further, the pitch P3, the distance between the upper end of the lid member 94B and the support grooves 1018 which are the lowermost support portions 1008, is set not more than the pitch P1 of the wafers W. Accordingly, the amount of a gas flowing into the space below the bottom section 94 can be significantly reduced, and the flow velocity of the gas, flowing between the lid member 94B and the lowermost wafer W, can be made approximately equal to the flow velocity of the gas flowing between the wafers W. This can prevent the occurrence of a turbulent gas flow in the bottom area of the support structure 38.

The pitch P3 is preferably equal to the pitch P1: P1=P3. However, because a dummy wafer is generally placed on the lowermost support grooves 1018 of the support portions 1008, the pitch P3 may be smaller than the pitch P1. Since the occurrence of a turbulent gas flow can thus be prevented in the bottom area of the support structure 38, the in-plane uniformity of the thickness of a film, formed on the surfaces of wafers W lying in the bottom area, and the quality of the film can be enhanced.

Further, in the bottom area of the support structure 38, the cover member 110 is provided on the topmost heat-retaining plate 73 of the heat-retaining stand 72 such that it occupies the space and, in addition, the ring-shaped flange portion 114 is provided around the upper end of the cover member 110 to reduce the amount of a gas flowing downward into the space below the flange portion 114. This can further prevent the occurrence of a turbulent gas flow in the bottom area of the support structure 38.

The respective gases, which have flown horizontally in laminar flow between the wafers W and through the top plate section 92 and the bottom section 94 in the support structure 38, are discharged smoothly, without change in the flow direction, from the slit-like exhaust port 52 which extends at least over the full length of the wafer boat in the vertical direction of the processing container 44. Accordingly, the occurrence of a turbulent gas flow in the area of the exhaust port 52 can be prevented. This can further prevent the occurrence of a turbulent gas flow in the top and bottom areas of the support structure 38.

The support structure (wafer boat) according to the first embodiment can be constructed merely by adding the secondary top plates 92B, the lid member 94B and the cover member 110 to the conventional wafer boat shown in FIG. 13, that is, without involving a substantial change of the design of the apparatus construction.

As described hereinabove, the present invention makes it possible to prevent the occurrence of a turbulent gas flow in the top and bottom areas of the processing container structure, thereby preventing a decrease in the in-plane uniformity of the thickness of a film formed and a decrease in the quality of the film.

Further, according to the present invention, a gas that has flown horizontally through the spaces between processing objects supported in the support structure is discharged, without change in the flow direction, from the slit-like exhaust port. This can further prevent the occurrence of a turbulent gas flow in the top and bottom areas of the processing container structure, thereby preventing a decrease in the in-plane uniformity of the thickness of a film formed and a decrease in the quality of the film.

<Experiments>

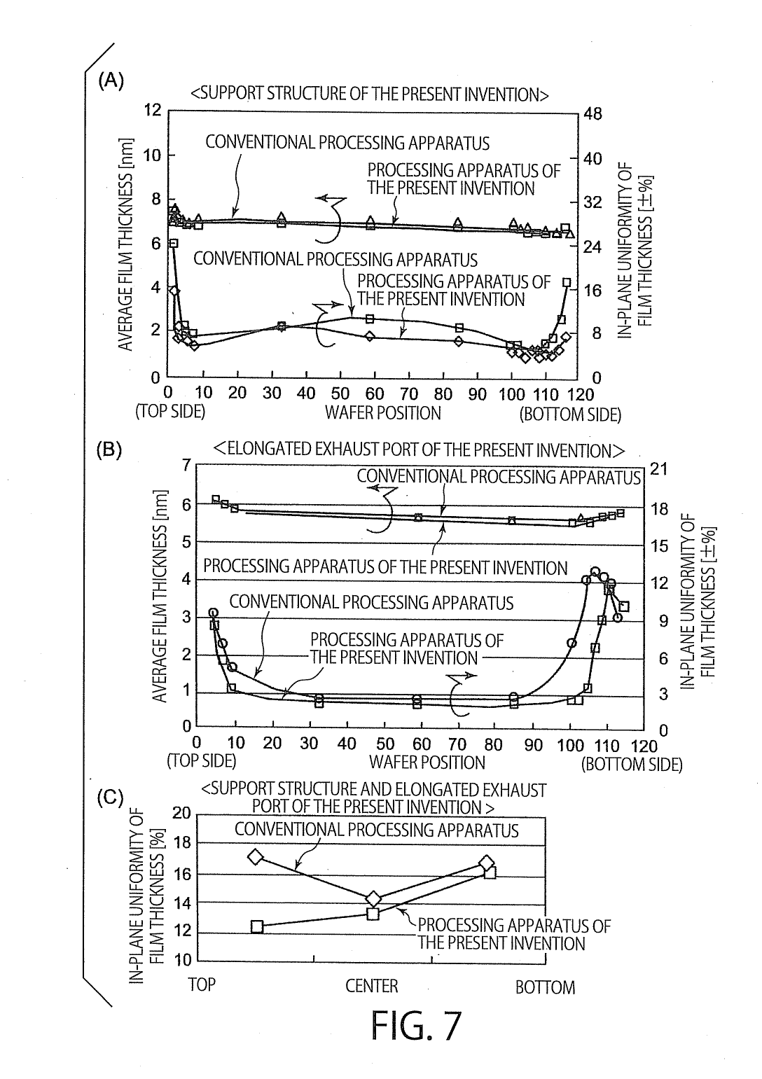

Film-forming experiments were conducted by using the below-described processing apparatuses according to the present invention. FIG. 7 shows the results of the experiments.

First, a film-forming experiment was conducted by using a processing apparatus that employs the above-described support structure (wafer boat) 38. In particular, the processing apparatus uses the support structure 38 which, as described above with reference to FIG. 4, is provided with the secondary top plates 92B, the lid member 94B, the cover member 110, etc. to eliminate large spaces in the top and bottom areas of the wafer boat, and uses the same processing container 44 as described above but having, instead of the exhaust port 52, a slit-like exhaust port 16 as shown in FIG. 12, whose length is shorter than the length of the support structure (wafer boat) 38. The results of the experiment are shown in FIG. 7(A). In FIG. 7(A), the abscissa indicates the wafer position; the “top side” indicates wafers lying in the top area of the support structure, and the “bottom side” indicates wafers lying in the bottom area of the support structure. The left ordinate indicates the average film thickness, and the right ordinate indicates the in-plane uniformity of film thickness. As a comparative experiment, the same film-forming experiment was conducted, but using the conventional processing apparatus shown in FIGS. 12 and 13. The results of the comparative experiment are also shown in FIG. 7(A).

As can be seen in FIG. 7(A), there is no substantial difference in the average film thickness between the use of the processing apparatus according to the present invention and the use of the conventional processing apparatus. With reference to the in-plane uniformity of film thickness, there is no substantial difference for wafers, lying at the wafer position of about 5 to 110, between the use of the processing apparatus according to the present invention and the use of the conventional processing apparatus. However, for wafers lying on the top side, at the wafer position of about 1 to 4, and for wafers lying on the bottom side, at the wafer position of about 111 to 118, the data shows that the use of the processing apparatus according to the present invention can obtain enhanced in-plane uniformity of film thickness especially for the bottom-side wafers.

Next, a film-forming experiment was conducted by using a processing apparatus that employs the above-described elongated exhaust port 52. In particular, the processing apparatus uses the slit-like exhaust port 52 whose length is equal to or longer than the length of the wafer boat, and uses as the wafer boat one having large spaces in the top and bottom areas as shown in FIG. 12. The results of the experiment are shown in FIG. 7(B). In FIG. 7(B), the abscissa indicates the wafer position; the “top side” indicates wafers lying in the top area of the support structure, and the “bottom side” indicates wafers lying in the bottom area of the support structure. The left ordinate indicates the average film thickness, and the right ordinate indicates the in-plane uniformity of film thickness. As a comparative experiment, the same film-forming experiment was conducted, but using the conventional processing apparatus shown in FIGS. 12 and 13. The results of the comparative experiment are also shown in FIG. 7(A).

As can be seen in FIG. 7(B), there is no substantial difference in the average film thickness between the use of the processing apparatus according to the present invention and the use of the conventional processing apparatus. With reference to the in-plane uniformity of film thickness, there is no substantial difference for wafers, lying at the wafer position of about 20 to 90, between the use of the processing apparatus according to the present invention and the use of the conventional processing apparatus. However, for wafers lying on the top side, at the wafer position of about 5 to 19, and for wafers lying on the bottom side, at the wafer position of about 91 to 110, the data shows that the use of the processing apparatus according to the present invention can obtain considerably enhanced in-plane uniformity of film thickness especially for the bottom-side wafers.

Next, a film-forming experiment was conducted by using a processing apparatus that employs both the above-described support structure (wafer boat) 38 and the above-described elongated exhaust port 52. In particular, the processing apparatus uses the support structure 38 which, as described above with reference to FIG. 4, is provided with the secondary top plates 92B, the lid member 94B, the cover member 110, etc. to eliminate large spaces in the top and bottom areas of the wafer boat, and uses the slit-like exhaust port 52 whose length is equal to or longer than the length of the wafer boat. The results of the experiment are shown in FIG. 7(C). In FIG. 7(C), the “top” indicates wafers lying in the top area of the support structure, the “center” indicates wafers lying in the central area of the support structure, and the “bottom” indicates wafers lying in the bottom area of the support structure. As a comparative experiment, the same film-forming experiment was conducted, but using the conventional processing apparatus shown in FIGS. 12 and 13. The results of the comparative experiment are also shown in FIG. 7(C).

As can be seen in FIG. 7(C), compared to the use of the conventional processing apparatus, the use of the processing apparatus according to the present invention can obtain enhanced in-plane uniformity of film thickness for all the wafers. The enhancement is greater for wafers lying in the center area to the top area of the support structure, especially for wafers lying in the top area.

<Evaluation of the Relationship Between the Opening Area of the Exhaust Port and the Cross-Sectional Area of the Exhaust Passage and Evaluation of the Width of the Exhaust Port>

An experiment was conducted to evaluate the relationship between the opening area of the slit-like exhaust port 52 and the cross-sectional area of the exhaust passage 86 in which the vacuum pump 90 is interposed. Further, an experiment was conducted to determine a gas flow velocity for varying widths of the slit-like exhaust port. In particular, the in-plane uniformity of film thickness was determined by simulation at varying ratios between the opening area of the slit-like exhaust port 52 and the cross-sectional area of the exhaust passage 86 [(Opening area of the exhaust port)/(Cross-sectional area of the exhaust passage)]. The width of the slit-like exhaust port was varied as follows: 2.5 mm, 5.0 mm and 10.0 mm.

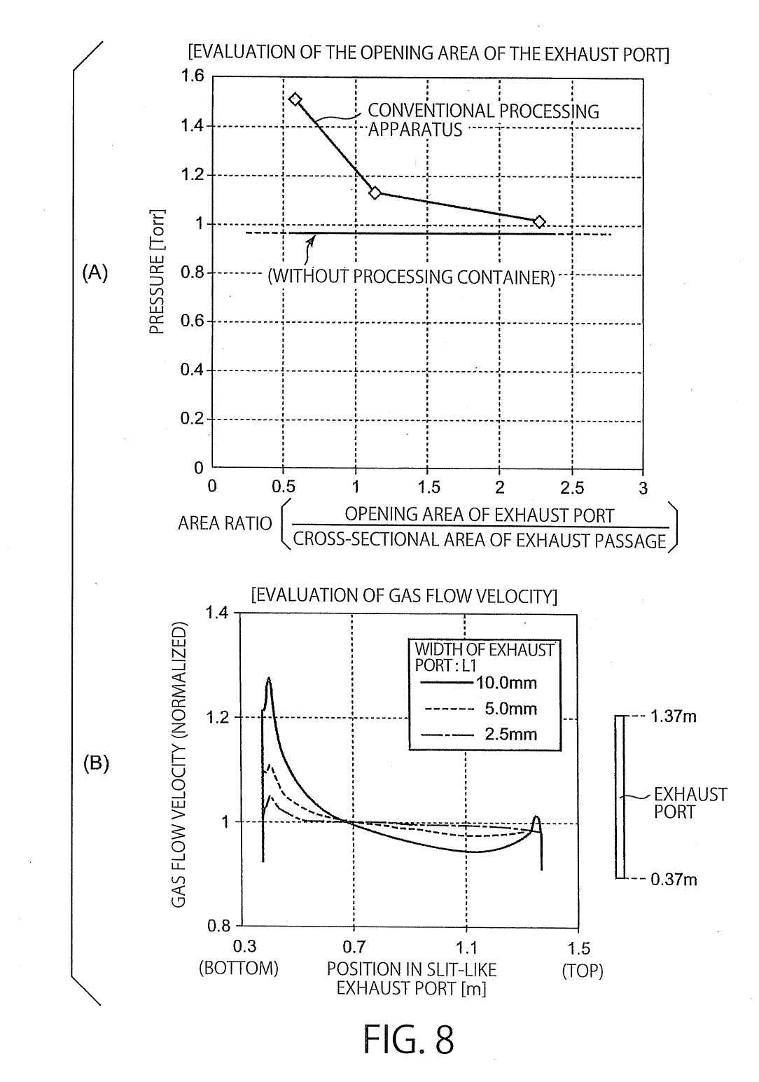

The results of the experiments are shown in FIGS. 8(A) and 8(B). FIG. 8(A) is a graph showing the relationship between the in-plane uniformity of film thickness and the ratio of the opening area of the exhaust port to the cross-sectional area of the exhaust passage, and FIG. 8(B) is a graph showing the relationship between the width of the exhaust port and the flow velocity of a gas in the longitudinal direction of the exhaust port. As shown in FIG. 8(A), as the above area ratio increases with increase in the width of the exhaust port, the pressure in the processing container 46 decreases and approaches 1 Torr and, though not shown in the graph, the in-plane uniformity of film thickness enhances. FIG. 8(A) also shows reference pressure data for a processing container structure solely comprised of the cover container 46, without the processing container 44 being provided. The results indicate that the area ratio is preferably not less than 0.5 in view of the processing pressure which may preferably be at most about 1.5 Torr, and is more preferably not less than 1 when the decrease in the processing pressure comes to saturation.

As described above, the width L1 of the slit-like exhaust port 52 is preferably in the range of 1 to 6 mm. As shown in FIG. 8(B), when the width of the exhaust port is 10.0 mm, the gas flow velocity is excessively large in the bottom area of the exhaust port, leading to poor uniformity of film thickness among wafers. On the other hand, when the width of the exhaust port is 5.0 mm or 2.5 mm, the gas flow velocity in the bottom area of the exhaust port is considerably lower and the distribution of the gas flow velocity in the longitudinal direction of the exhaust port is approximately uniform. The uniformity of film thickness among wafers is therefore enhanced. The results thus indicate that the width of the exhaust port is more preferably in the range of 2.5 to 5.0 mm.

### Second Embodiment

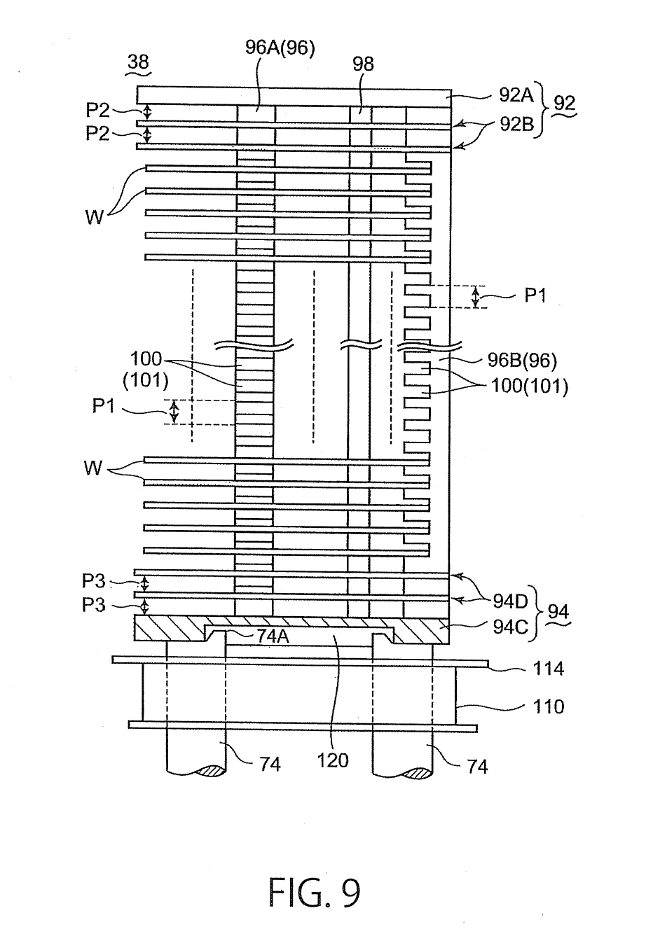

A support structure according to a second embodiment of the present invention will now be described. FIG. 9 shows a plan view of a support structure according to a second embodiment of the present invention. In FIG. 9, the same elements as those shown in FIG. 4 are given the same reference numerals, and a description thereof will be omitted.

In the second embodiment, the top plate section 92 of the support structure 38 has the same structure as that described above with reference to FIG. 4, and the bottom section 94 has a similar structure to the top plate section 92 as it is inverted. More specifically, a main bottom plate 94C without the central hole 104 (see FIG. 4) is used as the main bottom plate of the bottom section 94, and a recessed portion 120, with which the raised portions 74A of the support posts 74 are engaged, is provided in the back surface of the main bottom plate 94C. Because of the absence of the hole 104, the lid member 94B (see FIG. 4) is not provided, and instead one of more secondary bottom plates 94D, having the same structure as the above-described secondary top plate 92B, are provided at a predetermined pitch P3. The pitch P3 is set to be the same as the pitch P2 described above with reference to the secondary top plates 92B. The second embodiment can achieve the same advantageous effects as the above-described first embodiment.

### Third Embodiment

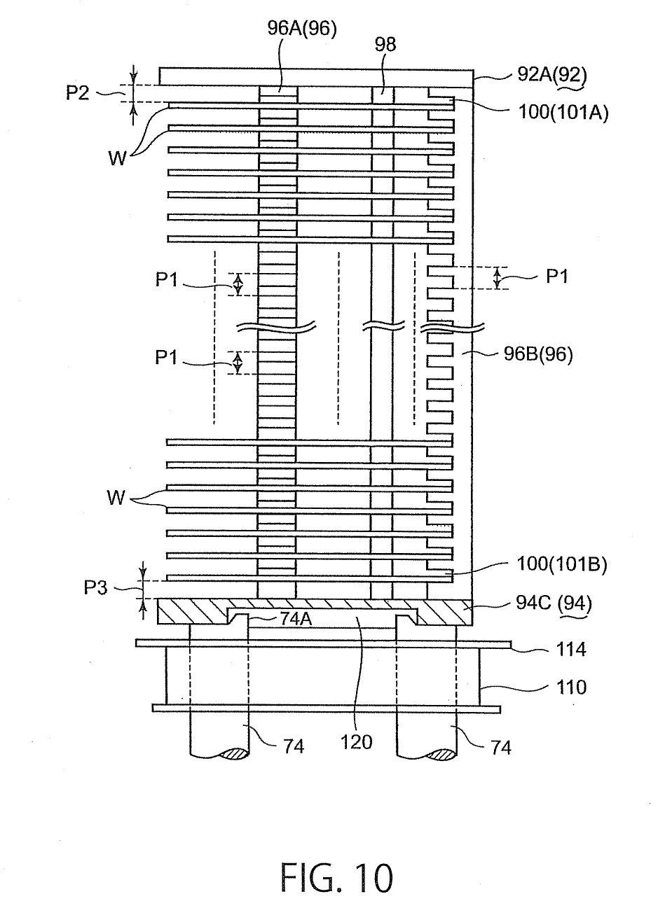

A support structure according to a third embodiment of the present invention will now be described. FIG. 10 shows a plan view of a support structure according to a third embodiment of the present invention. In FIG. 10, the same elements as those shown in FIGS. 4 and 9 are given the same reference numerals, and a description thereof will be omitted.

Though in the above-described second embodiment the secondary top plates 92B are used in the top plate section 92 of the support structure 38 and the secondary bottom plates 94D are used in the bottom section 94, it is possible to provide support grooves 101 as support portions 100 in place of the secondary top plates 92B and the secondary bottom plates 94D so that wafers W can be placed on those grooves. In this embodiment the top plate section 92 is comprised solely of the main top plate 92A and the bottom section 94 is comprised solely of the main bottom plate 94C. The distance between the main top plate 92A and the topmost wafer W is set at the above-described pitch P2, and the distance between the main bottom plate 94C and the lowermost wafer W is set at the above-described pitch P3. The third embodiment can achieve the same advantageous effects as the above-described first and second embodiments.

### Fourth Embodiment

Though in the above-described embodiments the processing container structure has a double tube structure consisting of the inner processing container 44 and the cover container 46 that surrounds the exterior of the container 44, the present invention is not limited to such a double tube structure. Thus, the present invention may be applied to a processing container structure of a single tube structure as disclosed e.g. in Japanese Patent Laid-Open Publication No. 2008-227460.

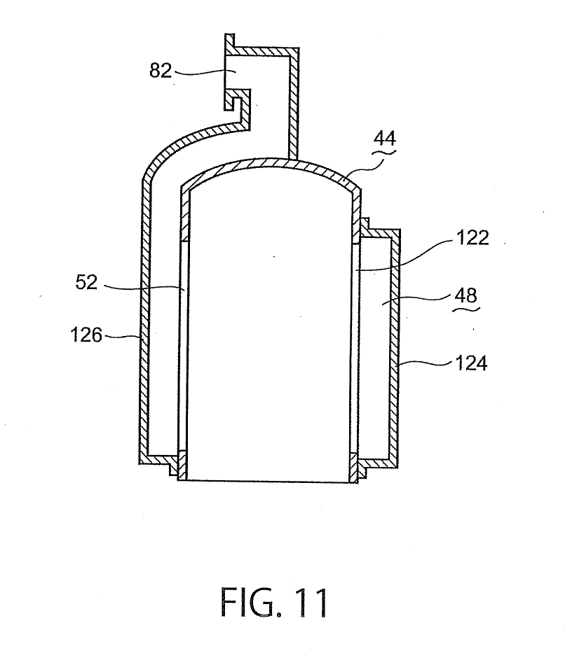

FIG. 11 shows a schematic view of a processing container structure according to a fourth embodiment of the present invention. Only the processing container structure is shown in FIG. 11, illustration of the other portion being omitted. The processing container structure of this embodiment comprises a processing container 44 of a single tube structure. The processing container 44 has on one side a vertically extending opening 122 and a compartment wall 124 that covers the opening 122. A nozzle housing area 48 is formed between the opening 122 and the compartment wall 124. A slit-like exhaust port 52 is formed in the wall of the processing container 44 in a position opposite the nozzle housing area 48, and an exhaust cover member 126 is provided such that it covers the exhaust port 52. The exhaust cover member 126 has, at its upper end, a gas outlet 82 from which a gas is discharged out of the system.

In the case of a processing container structure having a single tube structure, the container structure may be comprised solely of a quartz processing container without a manifold. The present invention, when applied to such a processing container structure, can achieve the same advantageous effects as describe above.

While the formation of a ZrOx film has been described by way of example, the present invention can be applied to the formation of any type of film. While the ALD film-forming method has been described by way of example, the present invention can, of course, be applied to other film-forming methods, for example the CVD method in which a raw material gas and a gas which reacts with the raw material gas are simultaneously supplied to wafers.

The present invention can also be applied to film-forming processing using a plasma. In that case, an electrode plate for application of a plasma-generating high frequency power is provided, for example, outside and along the longitudinal direction of the compartment wall of the raised portion 50 defining the nozzle housing area 48.

Semiconductor wafer as processing objects, usable in the present invention, include silicon wafers and compound semiconductor substrates such as GaAs, SIC, GaN, etc. The present invention can also be applied to other types of substrates, such as glass or ceramic substrates for use in liquid crystal display devices.

A comparative processing apparatus will now be described. FIG. 12 shows a schematic view of an exemplary comparative batch processing apparatus, and FIG. 13 shows a front view of a wafer boat. As shown in FIG. 12, the batch processing apparatus includes a processing container structure 6 consisting of a quartz processing container 2 with a closed top, and a quartz cover container 4 with a closed top, concentrically covering the circumference of the processing container 2. The bottom opening of the processing container structure 6 is openable and hermetically closable by a lid 8. A quartz wafer boat 10, holding wafers W in multiple stages, is housed in the processing container 2. The wafer boat 10 can be inserted upwardly into and withdrawn downwardly from the processing container structure 6. Gas nozzles 12, 14 are inserted into the processing container 2 from its bottom. The gas nozzles 12, 14 each have a large number of gas holes 12A, 12B arranged in the longitudinal direction of the nozzles, and necessary gases can be horizontally ejected from the gas holes 12A, 14A respectively at a controlled flow rate.

A vertically extending slit-like exhaust port 16 is formed in the side wall of the processing container 2 at a position opposite the gas nozzles 12, 14. A gas, exhausted from the exhaust port 16, can be exhausted out of the system from a gas outlet 18 provided in a lower portion of the side wall of the cover container 4. A cylindrical heater 19 for heating the wafers W supported in the wafer boat 10 is provided around the outer periphery of the processing container structure 6. The wafer boat 10 is placed on a heat-retaining stand 20 including a plurality of, for example four, quartz support posts 20A (only two posts are shown).

As shown in FIG. 13, the wafer boat 10 includes a top plate section 22, a bottom section 24, and a plurality of, for example three, support posts 26 (only two posts are shown in FIG. 13) which connect the top plate section 22 and the bottom section 24. The three support posts 26 are arranged at equal intervals along the semicircular arc portion of the circular contour of the wafer W.

Support grooves 27 are formed in each of the support posts 26 at a predetermined pitch P1, so that the wafers W can be supported in multiple stages by placing peripheral portions of the wafers W on the support grooves 27. Quartz reinforcing support posts 28, connecting the top plate section 22 and the bottom section 24, are each provided approximately midway between adjacent support posts 26. The bottom plate 24 is ring-shaped with a hole 29 formed in the center. A raised portion 21 at the top of each support post 20A of the heat-retaining stand 20 is engaged, with the peripheral surface of the hole 29 to hold the entire wafer boat 10.

In the processing apparatus, a film is deposited by ALD on the surface of each wafer W by horizontally ejecting a raw material gas and, for example, an oxidizing gas alternately and repeatedly from the gas holes 12A, 14A of the gas nozzles 12, 14. The gases in the processing container 2 are discharged from the slit-like exhaust port 16, and finally discharged out of the system from the gas outlet 18 provided in a lower portion of the side wall of the cover container 4.

The gas holes 12A, 14A of the gas nozzles 12, 14 are each formed at a position corresponding to the space between vertically adjacent wafers W so that the respective gases can be effectively supplied horizontally to the spaces between the wafers W even though the pitch P1 of the wafers is as small as about 6.5 mm.

As shown in FIG. 13, however, the vertical width of the space 30A between the topmost wafer W and the top plate section 22 and the vertical width of the space 30B between the lowermost wafer W and the bottom section 24 are set considerably larger than the pitch P1. Therefore, there is a difference between the velocity V1 of a gas flowing though the spaces 30A, 30B and the velocity of the gas flowing though the spaces of the pitch P1 between the wafers W, which causes a turbulent gas flow in the spaces 30A, 30B.

Because the bottom section 24 is ring-shaped, a gas flow 32, flowing downward though the central hole 29, also occurs. Consequently, a turbulent gas flow occurs more in the bottom space 30B. The occurrence of such a turbulent gas flow causes problems, such as decrease in the in-plane uniformity of the thickness of a film firmed or in the quality of the film in wafers W lying in the top and bottom areas of the boat.

Further, in the conventional processing apparatus, the length of the exhaust port 16, provided in the side wall of the processing container 2, is set shorter than the length of the wafer boat 10. Consequently, a gas that has flown horizontally though the top or bottom area of the wafer boat 10 changes its flow direction to a downward or upward direction before it passes though the exhaust port 16. This also causes the above-described turbulent gas flow.

In contrast, according to the present invention, the occurrence of a turbulent gas flow can be prevented as described above. Thus, the present invention enables enhancement of the in-plane uniformity of the thickness of a film formed on a wafer and enhancement of the quality of the film.

What is claimed is:

1. A support structure for supporting a plurality of objects to be processed and to be disposed in a processing container structure in which a processing gas flows horizontally from one side to the opposite side, comprising:
a top plate section;
a bottom section; and
a plurality of support posts connecting the top plate section and the bottom section,
wherein a plurality of support portions for supporting the objects to be processed are formed in each support post at a predetermined pitch along the longitudinal direction, and a distance between the topmost support portion of the support portions of each support post and the top plate section as well as a distance between the lowermost support portion of the support portions of each support post and the bottom section are set not more than the pitch of the support portions.

2. The support structure according to claim 1,
wherein the top plate section includes a topmost main top plate and a secondary top plate provided below the main top plate, and
wherein a distance between the main top plate and the adjacent secondary top plate is set not more than the pitch of the support portions.

3. The support structure according to claim 1,
wherein the bottom section includes a lowermost main bottom plate and a secondary bottom plates provided above the main bottom plate, and
wherein a distance between the main bottom plate and a adjacent secondary bottom plate is set not more than the pitch of the support portions.

4. The support structure according to claim 1,
wherein the bottom section includes a ring-shaped main bottom plate having a central hole, and a lid member that closes the hole.

5. The support structure according to claim 1,
wherein the top plate section and the bottom section are connected by a reinforcing support post.

6. A processing container structure for housing a plurality of objects to be processed and in which a processing gas flows horizontally from one side to the opposite side, comprising:
a quartz processing container with a closed top and an open bottom, configured to house the objects to be processed which are supported in a support structure;
a nozzle housing area for housing a gas nozzle, provided on one side of the processing container along the longitudinal direction; and
a slit-like exhaust port provided in the side wall of the processing container along the longitudinal direction at a position opposite the nozzle housing area, the upper end of the exhaust port being at the same or a higher level than the upper end of the support structure, and the lower end of the exhaust port being at the same or a lower level than the lower end of the support structure.

7. The processing container structure according to claim 6,
wherein the gas nozzle is provided along the longitudinal direction of the processing container and has a number of gas holes arranged at a predetermined pitch along the longitudinal direction.

8. The processing container structure according to claim 6,
wherein the opening area of the slit-like exhaust port is not less than 0.5 times the cross-sectional area of an exhaust passage connected to a vacuum pump for exhausting the atmosphere in the processing container, and the width of the slit-like exhaust port is not more than 6 mm.

9. A processing apparatus for carrying out predetermined processing of a plurality of objects to be processed, comprising:
a processing container structure having an open-bottom for housing the objects to be processed and in which a processing gas flows horizontally from one side to the opposite side; a lid for closing the bottom opening of the processing container structure;
a support structure for supporting the objects to be processed and which can be inserted into and withdrawn from the processing container structure;
a gas introduction means including a gas nozzle for introducing a gas into the processing container structure;
an exhaust means for exhausting the atmosphere in the processing container structure; and
a heating means for heating the processing objects,
wherein the processing container structure comprises
a quartz processing container with a closed top and an open bottom, configured to house the objects to be processed which are supported in a support structure;
a nozzle housing area for housing the gas nozzle, provided on one side of the processing container along the longitudinal direction; and a slit-like exhaust port provided in the side wall of the processing container along the longitudinal direction at a position opposite the nozzle housing area, the upper end of the exhaust port being at the same or a higher level than the upper end of the support structure, and the lower end of the exhaust port being at the same or a lower level than the lower end of the support structure, and
wherein the support structure comprises
a top plate section;
a bottom section; and
a plurality of support posts connecting the top plate section and the bottom section, wherein a plurality of support portions for supporting the objects to be processed are formed in each support post at a predetermined pitch along the longitudinal direction, and a distance between the topmost support portion of the support portions of each support post and the top plate section as well as a distance between the lowermost support portion of the support portions of each support post and the bottom section are set not more than the pitch of the support portions.
